(19) United States
(12) Patent Application Publication
(10) Pub. No.: US 2013/0048363 A1
(43) Pub. Date: Feb. 28, 2013

(54) CIRCUIT BOARD

(71) Applicants: CHENG-FEI WENG, Shenzhen City (CN); ZHENG-HENG SUN, Tu-Cheng (TW)

(72) Inventors: CHENG-FEI WENG, Shenzhen City (CN); ZHENG-HENG SUN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/304,374

(22) Filed: Nov. 24, 2011

(30) Foreign Application Priority Data
Aug. 24, 2011 (CN) 201110243356.4

(51) Int. Cl. H05K 1/11; H05K 3/00

(52) U.S. Cl. 174/261; 29/829

(57) ABSTRACT

A circuit board includes a board, a first signal trace and a second signal trace on the board, a first solder pad formed on the board and connected to a terminal of the first signal trace near to one end of the second signal trace, and a second pad formed on the board and connected to a terminal of the second signal trace near to the first solder pad. The second pad is apart from the first pad. The first pad or the second pad is coated with solder. After heated, the solder melts and spread to the second pad or the first pad, thereby connecting the first signal trace to the second signal trace.

### BACKGROUND

1. Technical Field

The present disclosure relates to a circuit board.

2. Description of Related Arts

Electronic switches, such as zero ohm resistors, can be found mounted on circuit boards being used as signal switchers, which adds to the cost of the circuit boards.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of an exemplary embodiment of a circuit board, wherein a first signal trace and a second signal trace are disconnected from each other.

FIG. 2 is similar to FIG. 1, but shows the first signal trace and the second signal trace are connected to each other.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

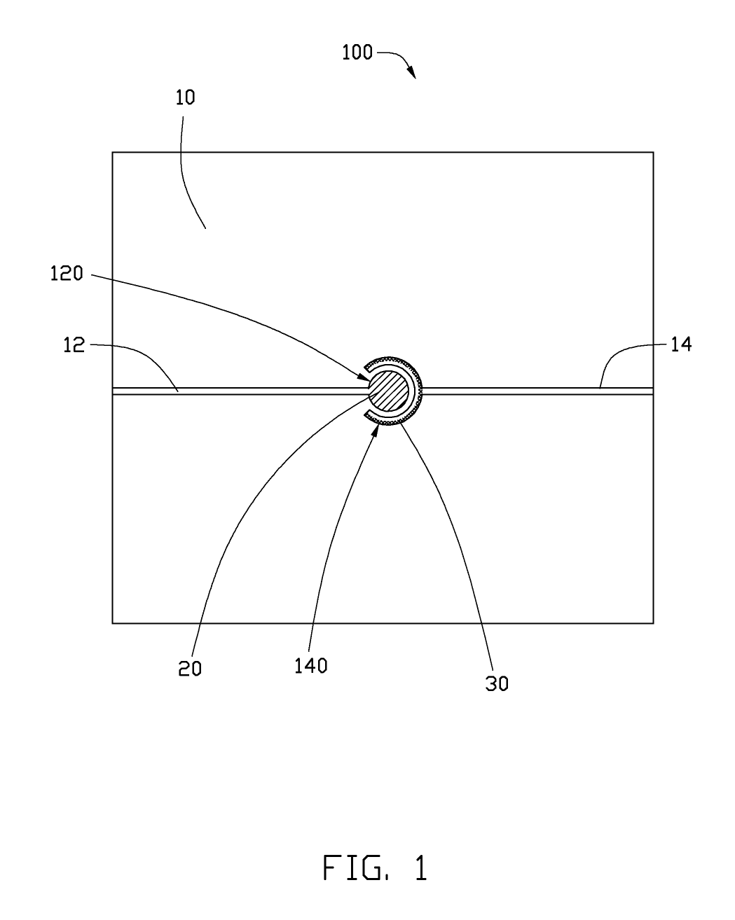

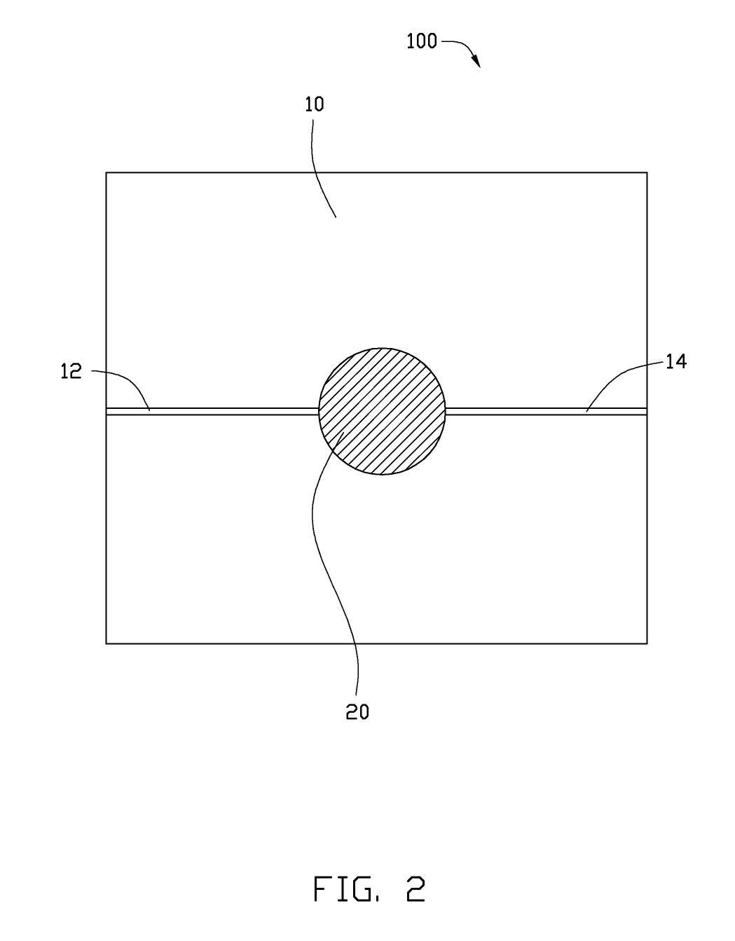

Referring to FIGS. 1-2, an exemplary embodiment of a circuit board 100 includes a board 10, and first and second signal traces 12, 14 on the board 10. A round first solder pad 120 is formed on the board 10 and connected to a terminal of the first signal trace 12 near one end of the second signal trace 14. A C-shaped second solder pad 140 is connected to a terminal of the second signal trace 14 and formed on the board 10 surrounding the first pad 120. The top outer edge of the second pad 140 is coated with solder resist 30. The first pad 120 is coated with solder 20. In other embodiments, the second pad 140 can be coated with solder 20.

In use, the solder 20 on the first pad 120 is heated to melt and spread to the second pad 140, thereby connecting the first signal trace 12 to the second signal trace 14. The coat of solder resist 30 prevents the solder 20 from flowing beyond the edge of the second pad 140, which prevents signal reflection at the joining of the signal traces 12, 14.

The foregoing description of the exemplary embodiments of the disclosure has been presented only for the purposes of illustration and description and is not intended to be exhaustive or to limit the disclosure to the precise forms disclosed. Many modifications and variations are possible. The embodiments were chosen and described in order to explain the principles of the disclosure and their practical application so as to enable others of ordinary skill in the art to utilize the disclosure and various embodiments and with such various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than by the foregoing description and the exemplary embodiments described therein.

What is claimed is:

1. A circuit board, comprising:
a board;
a first signal trace formed on the board;
a second signal trace formed on the board;
a first solder pad formed on the board and connected to a terminal of the first signal trace near to one end of the second signal trace; and
a second solder pad formed on the board and connected to a terminal of the second signal trace near to the first solder pad, wherein the second solder pad is apart from the first solder pad;
wherein the first solder pad or the second solder pad is coated with solder, the solder is operable to be heated to melt and spread to the second pad or the first pad, thereby connecting the first signal trace to the second signal trace.

2. The circuit board of claim 1, wherein the first solder pad is round, the second solder pad is substantially C-shaped and surrounds the first solder pad.

3. The circuit board of claim 2, wherein the solder is coated on the first solder pad, the top outer edge of the second solder pad is coated with solder resist.

4. A method for manufacturing a circuit board, comprising
providing a board;
forming a first signal trace on the board;
forming a second signal trace on the board;
forming a first solder pad on a terminal of the first signal trace near to one end of the second signal trace;
forming a second solder pad on a terminal of the second signal trace near to the first solder pad;
coating solder on the first solder pad or the second solder pad; and
heating the solder to melt and spread to the second solder pad or the first solder pad.

5. The method of claim 4, wherein the first pad is substantially round, the second solder pad is substantially C-shaped and surrounds the first solder pad.

6. The method of claim 4, wherein the top outer edge of the second solder pad is coated with solder resist.
